(19) United States
(12) Patent Application Publication
(10) Pub. No.: US 2025/0338413 A1
(43) Pub. Date: Oct. 30, 2025

(54) ASSEMBLY

(71) Applicant: FIVETECH TECHNOLOGY INC., New Taipei City (TW)

(72) Inventors: TING-JUI WANG, New Taipei City (TW); CHIA-CHING LIAO, New Taipei City (TW)

(73) Assignee: FIVETECH TECHNOLOGY INC., New Taipei City (TW)

(21) Appl. No.: 19/095,068

(22) Filed: Mar. 31, 2025

(30) Foreign Application Priority Data
Apr. 30, 2024 (TW) 113116208

(51) Int. Cl. H05K 5/02

(52) U.S. Cl. CPC H05K 5/0221; H05K 5/0286

(57) ABSTRACT

An assembly includes an assembling body, which includes a front groove, a clamping portion, a side groove and a first chute; and a fastening driving structure, which includes a grip and a connecting rod. A first end of the grip is pivoted to the assembling body, and a second end of the grip penetrates out of the front groove and is connected to a fastener. A second chute is formed between the two ends of the grip. A first end of the connecting rod is pivoted to the first chute and the second chute, and the second end of the connecting rod is provided with a jacking portion. A third chute is formed between the two ends of the connecting rod, and the third chute is pivoted to the assembling body.

### CROSS-REFERENCE TO RELATED APPLICATION

This non-provisional application claims priority under 35 U.S.C. § 119(a) on Patent Application No(s). 113116208 filed in Taiwan, R.O.C. on Apr. 30, 2024, the entire contents of which are hereby incorporated by reference.

### BACKGROUND OF THE INVENTION

### 1. Field of the Invention

The present disclosure relates to an assembly, and in particular, to an assembly which is simple to operate, labor-saving and convenient.

### 2. Description of the Related Art

When assembling two objects, screw locking is commonly adopted to ensure assembling stability and prevent mutual separating.

### BRIEF SUMMARY OF THE INVENTION

However, the above-mentioned method of screw locking is not only cumbersome in operation steps, but also needs tools such as screwdrivers, so when locking two objects with screws or disassembling and separating, both the problems of operation inconvenience and poor efficiency may be caused.

In view of the above shortcomings, the inventor supposed to achieve a perfect solution and took a deep study and finally developed an assembly with accumulated experience in the industry for many years, and the assembly allows a user to quickly manually fasten or separate at least two objects repeatedly without tools.

The directionality or its similar terms used in the present disclosure, such as “front”, “back”, “left”, “right”, “upper (top)”, “lower (bottom)”, “inside”, “outside”, and “side”, mainly refer to the direction of the accompanying drawings, and each directionality or its similar terms are only used for assisting in describing and understanding the embodiments of the present disclosure, and are not intended to limit the present disclosure.

The elements and components described throughout the present disclosure using the article “a/an” or “one” are employed only for convenience of usage and to convey the common meaning within the scope of the present disclosure. Such terms shall be construed to include one or at least one instances, and the singular concept encompasses plural instances unless the context clearly dictates otherwise.

The similar terms such as “connecting”, “combining” or “assembling” used in the present disclosure mainly include the forms that the components can be separated without destroying after being connected, or the components may be inseparable after being connected, and those of ordinary skill in the art can choose according to materials or assembling requirements of components to be connected.

To achieve the above purpose and other purposes, the present disclosure provides an assembly. The assembly includes: an assembling body, which includes a front groove, a clamping portion, a side groove and a first chute; and a fastening driving structure, which includes a grip and a connecting rod. A first end of the grip is pivoted to the assembling body, and a second end of the grip penetrates out of the front groove and is connected to a fastener. A second chute is formed between the two ends of the grip. A first end of the connecting rod is pivoted to the first chute and the second chute, and the second end of the connecting rod is provided with a jacking portion. A third chute is formed between the two ends of the connecting rod, and the third chute is pivoted to the assembling body. When the assembly is in a lock state, the jacking portion penetrates out of the side groove, and the fastener is connected to the clamping portion; and when the assembly is in an open state, the jacking portion retracts into the assembling body, and the fastener moves away from the assembling body.

The present disclosure further provides an assembly. The assembly includes: an assembling body, which includes a front groove, a side groove or a first chute or a clamping portion; or a fastening driving structure, which includes a grip or a connecting rod; or a first end of the grip is pivoted to the assembling body, or a second end of the grip penetrates out of the front groove or is connected to a fastener, or a second chute is formed between the two ends of the grip; or a first end of the connecting rod is pivoted to the first chute or the second chute, or the second end of the connecting rod is provided with a jacking portion, or a third chute is formed between the two ends of the connecting rod, or the third chute is pivoted to the assembling body; or when the assembly is in a lock state, the jacking portion penetrates out of the side groove, or the fastener is connected to the clamping portion; or when the assembly is in an open state, the jacking portion retracts into the assembling body, or the fastener moves away from the assembling body.

The present disclosure further provides an assembly, which includes: an assembling body, which includes a fastening driving structure; or the fastening driving structure includes a grip or a connecting rod, or a first end of the grip is pivoted to the assembling body, or a second end of the grip penetrates out of a front groove or is connected to a fastener, or a second chute is formed between the two ends of the grip; or a first end of the connecting rod is pivoted to a first chute or the second chute, or the second end of the connecting rod is provided with a jacking portion, or a third chute is formed between the two ends of the connecting rod, or the third chute is pivoted to the assembling body; or the assembling body is provided with the front groove, a side groove or the first chute or a clamping portion; or when the assembly is in a lock state, the jacking portion penetrates out of the side groove, or the fastener is connected to the clamping portion; or when the assembly is in an open state, the jacking portion retracts into the assembling body, or the fastener moves away from the assembling body.

In the above assembly, the assembling body may be provided with a first housing and a second housing. The assembling body may be provided with a fixed shaft rod, a first sliding shaft rod and a second sliding shaft rod that are connected to the first housing and/or the second housing. The fixed shaft rod may penetrate through the first end of the grip. The first sliding shaft rod may penetrate through the first chute and the second chute. The second sliding shaft rod may penetrate through the third chute.

In the above assembly, each of the first housing and the second housing may be provided with two through holes and an elongated slot. The fixed shaft rod and the second sliding shaft rod may penetrate through the two corresponding through holes of the first housing and the second housing respectively. The two elongated slots may jointly form the first chute.

In the above assembly, the grip may be provided with a first corner portion connected to a first base and a first outward-turning portion. A first obtuse angle may be formed between an extension direction of the first base and an extension direction of the first outward-turning portion. The second chute is positioned in the first outward-turning portion. The fastener is connected to the first base.

In the above assembly, the connecting rod may be provided with a second corner portion connected to a second base and a second outward-turning portion. A second obtuse angle may be formed between an extension direction of the second base and an extension direction of the second outward-turning portion. The jacking portion is positioned on the second outward-turning portion and may be located within the range of the second obtuse angle. The third chute is positioned in the second base.

In the above assembly, the connecting rod may be provided with a third outward-turning portion connected to the second base. A third obtuse angle may be formed between the extension direction of the second base and an extension direction of the third outward-turning portion. The second obtuse angle and the third obtuse angle may be alternate interior angles relative to each other.

In the above assembly, the extension direction of the second outward-turning portion may be parallel to the extension direction of the third outward-turning portion.

In the above assembly, the first outward-turning portion of the grip may be provided with a side slot. The second chute is aligned in the side slot. The third outward-turning portion of the connecting rod may be a thin sheet and may penetrate into the side slot. The assembling body may be provided with the first sliding shaft rod penetrating through the first chute, the second chute, the side slot and the third outward-turning portion.

In the above assembly, one end of the fastener may be provided with a fastening body, the other end may be abutted by an elastic member; and the two ends of the fastener may be pivoted to the second end of the grip.

In the above assembly, the assembling body may be arranged or assembled or integrally formed in a data center or a case or a cabinet or a computer or a sliding rail or a mainboard or a printed circuit board or a metallic body or a nonmetallic body or a plastic body or a housing or an object, or the jacking portion may be configured to jack or hook or push the case or the cabinet or the computer or the sliding rail or the mainboard or the printed circuit board or the metallic body or the nonmetallic body or the plastic body or the housing or the object, or the jacking portion may be configured to jack or hook or push the case or the cabinet or the computer or the sliding rail or the mainboard or the printed circuit board or the metallic body or the nonmetallic body or the plastic body or the housing or the object to move the object arranged or assembled or integrally formed by the assembling body.

In addition, the present disclosure further provides an assembling method for an assembly, which includes the following steps: providing an assembling body, which includes a front groove, a clamping portion, a side groove and a first chute; and providing a fastening driving structure, which includes a grip and a connecting rod. A first end of the grip is pivoted to the assembling body, and a second end of the grip penetrates out of the front groove and is connected to a fastener. A second chute is formed between the two ends of the grip. A first end of the connecting rod is pivoted to the first chute and the second chute, and the second end of the connecting rod is provided with a jacking portion. A third chute is formed between the two ends of the connecting rod, and the third chute is pivoted to the assembling body. When the assembly is in a lock state, the jacking portion penetrates out of the side groove, and the fastener is connected to the clamping portion; and when the assembly is in an open state, the jacking portion retracts into the assembling body, and the fastener moves away from the assembling body.

The present disclosure further provides an assembling method for an assembly, which includes the following steps: providing an assembling body, which includes a front groove, a side groove or a first chute or a clamping portion; or providing a fastening driving structure, which includes a grip or a connecting rod; or a first end of the grip is pivoted to the assembling body, or a second end of the grip penetrates out of the front groove or is connected to a fastener, or a second chute is formed between the two ends of the grip; or a first end of the connecting rod is pivoted to the first chute or the second chute, or the second end of the connecting rod is provided with a jacking portion, or a third chute is formed between the two ends of the connecting rod, or the third chute is pivoted to the assembling body; when the assembly is in a lock state, the jacking portion penetrates out of the side groove, or the fastener is connected to the clamping portion; or when the assembly is in an open state, the jacking portion retracts into the assembling body, or the fastener moves away from the assembling body.

The present disclosure further provides an assembling method for an assembly, which includes the following steps: providing an assembling body, which includes a fastening driving structure; or the fastening driving structure includes a grip or a connecting rod, or a first end of the grip is pivoted to the assembling body, or a second end of the grip penetrates out of a front groove or is connected to a fastener, or a second chute is formed between the two ends of the grip; or a first end of the connecting rod is pivoted to a first chute or the second chute, or the second end of the connecting rod is provided with a jacking portion, or a third chute is formed between the two ends of the connecting rod, or the third chute is pivoted to the assembling body; or the assembling body is provided with the front groove, a side groove or the first chute or a clamping portion; or when the assembly is in a lock state, the jacking portion penetrates out of the side groove, or the fastener is connected to the clamping portion; or when the assembly is in an open state, the jacking portion retracts into the assembling body, or the fastener moves away from the assembling body.

Therefore, according to the assembly and the assembling method therefor provided by the present disclosure, a user can simply manually pivot the grip, and then enable the fastener to be hooked and connected with the clamping portion after pivoting to a designated position, so as to hook and connect the object by the jacking portion that penetrates out of the assembling body, thus quickly completing the operation of stably assembling the assembly to the object; and in addition, tools are not needed in the operation process, so effects of improving the operation convenience and efficiency and the like can be achieved.

### BRIEF DESCRIPTION OF THE DRAWINGS

FIG. 1 is a schematic three-dimensional exploded diagram according to an embodiment of the present disclosure.

FIG. 2 is a schematic three-dimensional diagram of an open state from another perspective according to an embodiment of the present disclosure.

FIG. 3 is a schematic three-dimensional exploded diagram of a fastening driving structure according to an embodiment of the present disclosure.

FIG. 4 is a partial top view of an open state according to an embodiment of the present disclosure, where a second housing of an assembling body is omitted.

FIG. 5 is a partial top view of switching from an open state to an unlock state according to an embodiment of the present disclosure, where a second housing of an assembling body is omitted.

FIG. 6 is a partial top view of an unlock state according to an embodiment of the present disclosure, where a second housing of an assembling body is omitted.

FIG. 7 is a partial top view of a lock state according to an embodiment of the present disclosure, where a second housing of an assembling body is omitted.

FIG. 8 is a top view of a grip according to an embodiment of the present disclosure.

FIG. 9 is a top view of a connecting rod according to an embodiment of the present disclosure.

FIG. 10 is a partial top view of a side frame of a frame body according to another embodiment of the present disclosure.

FIG. 11 is a schematic diagram of an action of bringing an object into a frame body by means of an assembly according to another embodiment of the present disclosure.

### DETAILED DESCRIPTION OF THE INVENTION

To fully understand the purpose, features and efficacy of the present disclosure, the present disclosure is described in detail by means of the following specific embodiments in cooperation with the accompanying drawings.

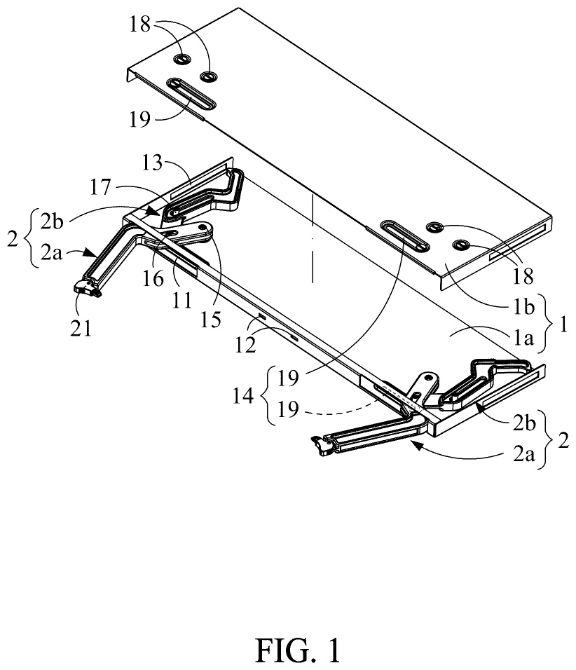

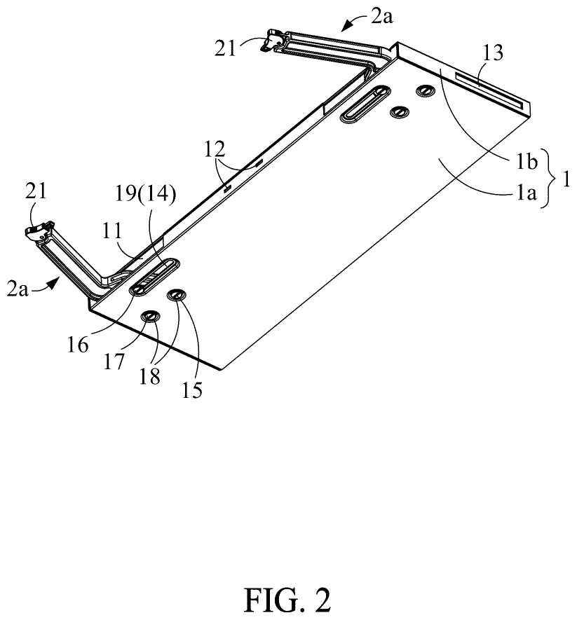

Referring to FIG. 1 and FIG. 2, which show a preferred embodiment of an assembly according to the present disclosure. The assembly includes an assembling body 1 and at least one fastening driving structure 2, and the fastening driving structure 2 is partially pivoted in the assembling body 1.

An object to be assembled may be accommodated inside the assembling body 1, such as hard disks or circuit boards or other electronic devices, but are not limited thereto. The form of the assembling body 1 may be different according to needs, and the number of the fastening driving structures 2 is selected to be matched with the form of the assembling body 1 and the form of a frame body to be assembled. For example, when the assembling body 1 is in a form with a large length-width ratio difference as shown in FIG. 1, one fastening driving structure 2 may be arranged on each of a left side and a right side of the assembly to improve the stability when assembling to the frame body. In contrast, for an assembling body 1 with a small length-width ratio difference, if arranging only one fastening driving structure 2 is able to realize stable assembling to the frame body, the number of the fastening driving structure 2 of the assembly may be one, but is not limited thereto.

Specifically, the assembling body 1 may be provided with a front groove 11, a clamping portion 12, a side groove 13 and a first chute 14 for each fastening driving structure 2. After the assembly is assembled to the frame body, a front end of the assembling body 1 faces a user. In this embodiment, an end surface of the front end of the assembling body 1 may be closed, the front groove 11 may penetrate through the end surface of the front end of the assembling body 1 to communicate the interior with the exterior of the assembling body 1; and the clamping portion 12 may be, for example, a small hole that penetrates through the end surface of the front end of the assembling body 1 for clamping and locking by the fastening driving structure 2 (described in detail below). In other embodiments, the end surface of the front end of the assembling body 1 may also be opened or partially opened, and the clamping portion 12 may be, for example, a column adjacent to the front end of the assembling body 1 for clamping and locking by the fastening driving structure 2. The side groove 13 may penetrate through an end surface of a left side or a right side of the assembling body 1 to communicate the interior with the exterior of the assembling body 1 in another direction.

Referring to FIG. 1 to FIG. 4, the fastening driving structure 2 is provided with a grip 2a and a connecting rod 2b. A first end of the grip 2a is pivoted to the assembling body 1, for example, pivoted into the assembling body 1, and a second end of the grip 2a penetrates out of the front groove 11 and is connected to a fastener 21. The fastener 21 is detachably connected to the clamping portion 12 of the assembling body 1. A second chute 22 is formed between the two ends of the grip 2a. A first end of the connecting rod 2b is pivoted to the first chute 14 and the second chute 22, and the second end of the connecting rod 2b is provided with a jacking portion 23. The jacking portion 23, for example, may be in a hook shape. A third chute 24 is formed between the two ends of the connecting rod 2b, and the third chute 24 is pivoted to the assembling body 1.

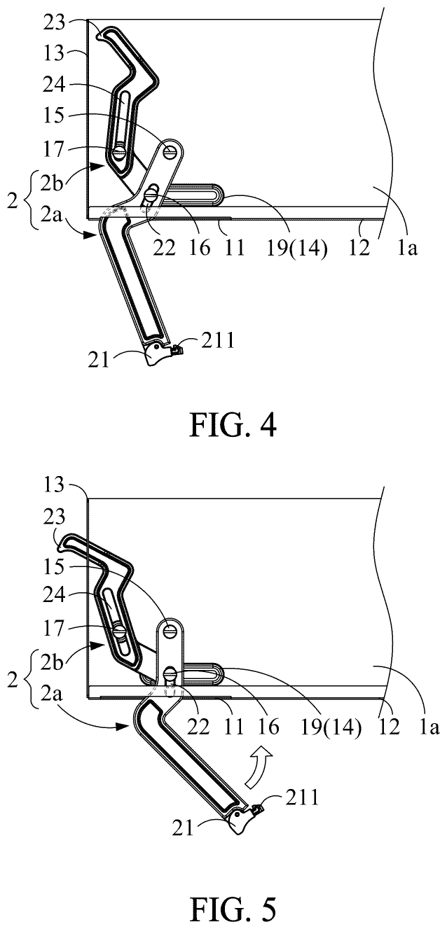

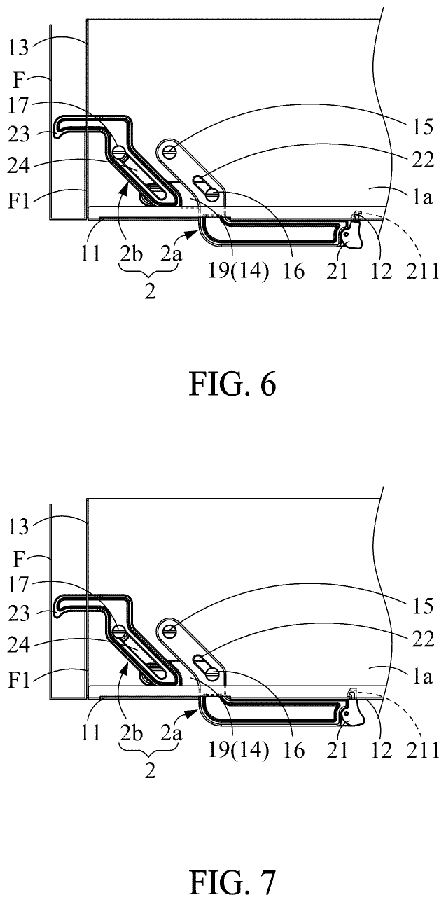

Referring to FIG. 4, when the assembly is in an open state, the jacking portion 23 retracts into the assembling body 1, so that the fastener 21 moves away from the assembling body 1. At this time, the user may dispose the assembly between two side frames F (marked in FIG. 6) of the frame body.

Referring to FIG. 5, in a process of switching the assembly from the open state to an unlock state, the user may push the second end of the grip 2a towards the assembling body 1, then the grip 2a is made to pivot with the first end thereof as the center, thus the position of the second chute 22 of the grip 2a relative to the first chute 14 is changed, and further, the connecting rod 2b is linked to be pivoted to the first chute 14 and a first end of the second chute 22 at the same time, then the connecting rod 2b is made to pivot, and the jacking portion 23 of the connecting rod 2b may penetrate out of the assembling body 1 through the side groove 13.

Referring to FIG. 6, when the assembly is switched to the unlock state, the jacking portion 23 penetrates out of the side groove 13 of the assembling body 1 and extends into the corresponding side frame F of the frame body. A side edge, on the same side with the jacking portion 23, of the connecting rod 2b may be abutted against an inner extension plate F1 of the side frame F to improve the connecting stability. On the other hand, the grip 2a is pivoted to a position that is closest to the assembling body 1, and the fastener 21 may be adjacent to the clamping portion 12 of the assembling body 1.

Referring to FIG. 7, the fastener 21 may be further hooked to be connected to the clamping portion 12 of the assembling body 1, so as to maintain that the fastening driving structure 2 is locked and cannot be pivoted temporarily and to switch the assembly to a lock state.

Therefore, after disposing the assembly in this embodiment into a preset position of the frame body, the user may simply manually pivot the grip 2a, and then enable the fastener 21 to be hooked and connected with the clamping portion 12 after pivoting to a designated position, so as to hook and connect the object by the jacking portion 23 that penetrates out of the assembling body, thus quickly completing the operation of stably assembling the assembly to the object; and in addition, tools are not needed in the operation process, so effects of improving the operation convenience and efficiency and the like can be achieved.

When the user disposes the assembly in this embodiment between the two side frames F of the frame body, it does not need to completely dispose the assembling body 1, for example, only half of the assembling body 1 may be disposed between the two side frames F. In the process of switching the assembly from the open state shown in FIG. 4 to the unlock state shown in FIG. 6, because the grip 2a can be pushed to be linked with the second end of the connecting rod 2b to extend out of the assembling body 1, a portion, extending out of the assembling body 1, of the connecting rod 2b may be abutted against the inner extension plates F1 of the side frames F, and in the process of continuously pivoting to the designated position, the whole assembly is brought into the frame body, thereby further improving the convenience in operation.

When the assembly in this embodiment is to be separated from the frame body, it is only needed to unlock the fastener 21 from the clamping portion 12 of the assembling body 1, then the second end of the grip 2a may be pulled to pivot in a direction away from the assembling body 1, and therefore the fastening driving structure 2 may revert to the state shown in FIG. 4 from the state shown in FIG. 7, the jacking portion 23 of the connecting rod 2b retracts into the assembling body 1, and the assembly may be smoothly drawn out from the position between the two side frames F. In this process, tools are not needed, so the operation of separating the assembly from the frame body can be rapidly completed.

In addition, when the assembly in this embodiment is used for connecting an electronic device such as a hard disk or a circuit board by the assembling body 1, the assembling body 1 may be disposed at a preset position on a rack, and the fastening driving structure 2 is operated to be in the lock state, thus the assembly is stably connected to the rack without falling out forwards, and moreover, the electronic device may be electrically connected with a connecting port configured in the rack. When the electronic device is required to be removed, it is only needed to switch the assembly from the lock state shown in FIG. 7 to the open state shown in FIG. 4, then the assembly and the electronic device connected thereby may be smoothly drawn out, and moreover, the electronic device is separated from the connecting port configured in the rack.

Referring to FIG. 1 to FIG. 4, besides the above embodiments, in one embodiment of the present disclosure, the assembling body 1 may be further provided with a first housing 1a and a second housing 1b. The first housing 1a and the second housing 1b may be oppositely covered to jointly form a hollowed-out structure. The assembling body 1 may be provided with a fixed shaft rod 15, a first sliding shaft rod 16 and a second sliding shaft rod 17 that are connected to the first housing 1a and/or the second housing 1b. The fixed shaft rod 15 penetrates through the first end of the grip 2a to serve as an axis of the grip 2a during pivoting. The first sliding shaft rod 16 penetrates through the first chute 14 and the second chute 22, and the position in the first chute 14 and/or the second chute 22 may be changed to limit a track of the grip 2a during pivoting and simultaneously link the connecting rod 2b. The second sliding shaft rod 17 penetrates through the third chute 24, and the position in the third chute 24 may be changed to limit a track of the connecting rod 2b during pivoting. Therefore, the assembling body 1 in this embodiment may position the grip 2a and the connecting rod 2b and limit the grip 2a and the connecting rod 2b to pivot according to a preset track by a simple structure which is easy to form, so that the assembly in this embodiment has the effects of easiness in manufacturing, assembly, operation and the like.

Referring to FIG. 1, FIG. 2 and FIG. 4, in one embodiment of the present disclosure, each of the first housing 1a and the second housing 1b may be provided with two through holes 18 and an elongated slot 19 for each fastening driving structure 2. When the first housing 1a and the second housing 1b are oppositely covered, the two through holes 18 of the first housing 1a are coaxial with the two through holes 18 of the second housing 1b respectively, and thus the fixed shaft rod 15 and the second sliding shaft rod 17 may penetrate through the two corresponding through holes 18 of the first housing 1a and the second housing 1b. In addition, in the axial direction of the through holes 18, a projection of the elongated slot 19 of the first housing 1a coincides with that of the elongated slot 19 of the second housing 1b, and the two elongated slots 19 jointly form the first chute 14. Therefore, in this embodiment, the fixed shaft rod 15, the first sliding shaft rod 16 and the second sliding shaft rod 17 may penetrate into the assembling body 1 in a middle section, and the first housing 1a and the second housing 1b are correspondingly clamped by the two ends so that the first housing 1a and the second housing 1b are kept connected. Accordingly, in this embodiment, the structure of the assembling body 1 can be simplified, so that components of the assembling body 1 are convenient for manufacturing and assembling, and moreover, the effect of limiting the fastening driving structures 2 is achieved.

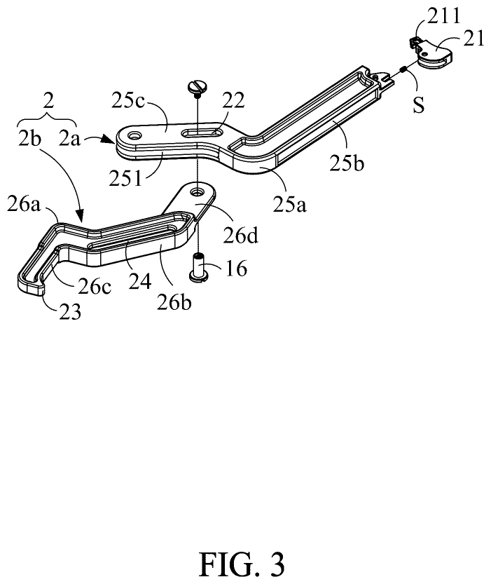

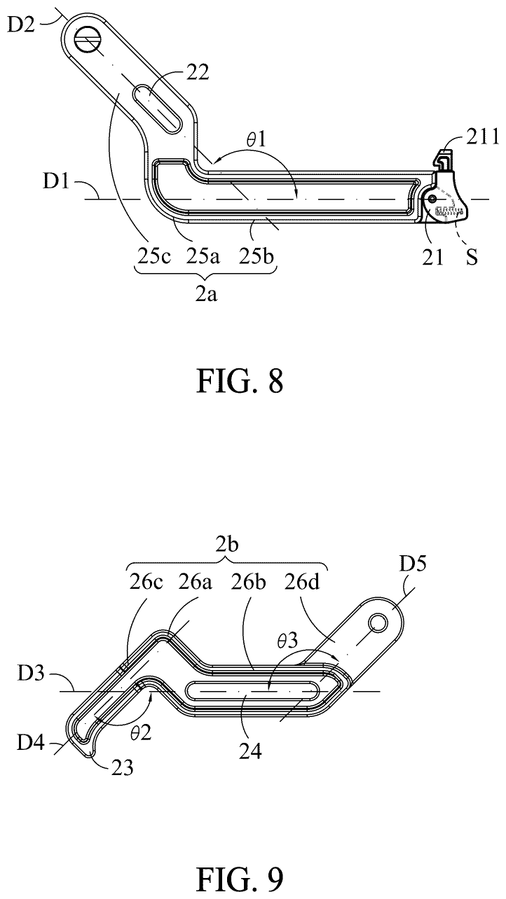

Referring to FIG. 1, FIG. 3 and FIG. 8, besides the above embodiments, in one embodiment of the present disclosure, the grip 2a is provided with a first corner portion 25a that is connected to a first base 25b and a first outward-turning portion 25c. A first obtuse angle θ1 is formed between an extension direction D1 of the first base 25b and an extension direction D2 of the first outward-turning portion 25c. The second chute 22 is located in the first outward-turning portion 25c. The fastener 21 is connected to the first base 25b. Therefore, the grip 2a in this embodiment may be in a form easy to form, and can accurately achieve the above-mentioned motion track.

Referring to FIG. 1, FIG. 3 and FIG. 9, in one embodiment of the present disclosure, the connecting rod 2b is provided with a second corner portion 26a that is connected to a second base 26b and a second outward-turning portion 26c. A second obtuse angle θ2 is formed between an extension direction D3 of the second base 26b and an extension direction D4 of the second outward-turning portion 26c. The jacking portion 23 is positioned on the second outward-turning portion 26c and located within the range of the second obtuse angle θ2. The third chute 24 is positioned in the second base 26b. In addition, the second base 26b may be further connected to a third outward-turning portion 26d. A third obtuse angle θ3 is formed between the extension direction D3 of the second base 26b and an extension direction D5 of the third outward-turning portion 26d, and the second obtuse angle θ2 and the third obtuse angle θ3 are alternate interior angles relative to each other. In addition, the extension direction D4 of the second outward-turning portion 26c and the extension direction D5 of the third outward-turning portion 26d may be parallel to each other, but is not limited thereto. Therefore, the connecting rod 2b in this embodiment may be in the form easy to form, and can accurately achieve the motion track.

Referring to FIG. 1 to FIG. 3, in one embodiment of the present disclosure, the first outward-turning portion 25c of the grip 2a is provided with a side slot 251, and the second chute 22 is aligned in the side slot 251. The third outward-turning portion 26d of the connecting rod 2b is a thin sheet. The third outward-turning portion 26d penetrates into the side slot 251, and the first sliding shaft rod 16 penetrates through the first chute 14, the second chute 22, the side slot 251 and the third outward-turning portion 26d. Therefore, the fastening driving structure 2 in this embodiment can realize a relatively-displaceable pivoting relationship between the grip 2a and the connecting rod 2b without increasing the thickness of the fastening driving structure 2 by a structure that is easy to form and assemble.

Referring to FIG. 3, FIG. 6 and FIG. 7, besides the above embodiments, in one embodiment of the present disclosure, one end of the fastener 21 is provided with a fastening body 211, the other end is abutted against an elastic member S, and the two ends of the fastener 21 are pivoted to the second end of the grip 2a (an end portion, not connected to the first corner portion 25a, of the first base 25b). Therefore, when the assembly is switched to the unlock state as shown in FIG. 6, the fastening body 211 of the fastener 21 may penetrate into the clamping portion 12 of the assembling body 1, then the user pivots the fastener 21 to hook the edge of the clamping portion 12 with the fastening body 211 and compress the elastic member S, and thereby the assembly is switched to the lock state as shown in FIG. 7. Accordingly, the fastener 21 in this embodiment may be stably fastened to the clamping portion 12 of the assembling body 1 through a simple structure, and it is guaranteed that the whole fastening driving structure 2 is kept in the lock state without unexpected pivoting.

Besides the above embodiments, in one embodiment of the present disclosure, the assembling body 1 may also be arranged or assembled or integrally formed in a data center or a case or a cabinet or a computer or a sliding rail or a mainboard or a printed circuit board or a metallic body or a nonmetallic body or a plastic body or a housing or an object; or the jacking portion 23 may be configured to jack or hook or push the case or the cabinet or the computer or the sliding rail or the mainboard or the printed circuit board or the metallic body or the nonmetallic body or the plastic body or the housing or the object.

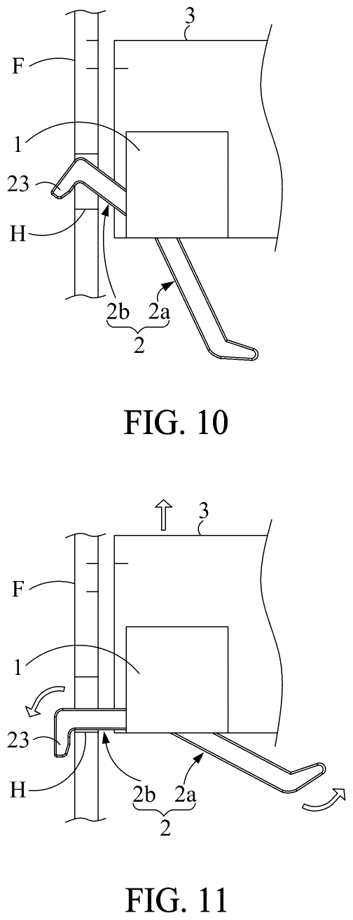

Alternatively, referring to FIG. 10 and FIG. 11, in one embodiment of the present disclosure, the assembling body 1 may be arranged or assembled on an object 3, or integrally connected to the object 3. Accordingly, the user may manually pivot the grip 2a to enable the jacking portion 23 of the connecting rod 2b to penetrate out of the side groove 13 of the assembling body 1 and a side edge of the object 3. The jacking portion 23 is hooked and connected to the corresponding side frame F of the frame body, or penetrates into the hole H of the corresponding side frame F, and therefore the operation of stably assembling the object 3 connected with the assembly to the frame body is rapidly completed. Because the grip 2a is pushed to link with the second end of the connecting rod 2b to extend out of the assembling body 1 and the object 3, the portion, extending out of the assembling body 1 and the object 3, of the connecting rod 2b may abut against the end edge of the hole H of the corresponding side frame F (or an inner extension plate F1 of the side frame F shown in the FIG. 6), and the object 3 connected with the assembly is brought into the frame body in the process of continuously pivoting to the designated position.

The present disclosure has been disclosed in the above with preferred embodiments, but those skilled in the art should understand that the embodiments are only used for describing the present disclosure and should not be construed as limiting the scope of the present disclosure. It is to be noted that all changes and substitutions equivalent to the embodiments should fall within the scope of the present disclosure. Therefore, the scope of protection of the present disclosure shall be subject to the definition of the claims.

What is claimed is:

1. An assembly, comprising:
an assembling body, comprising a fastening driving structure, or the fastening driving structure comprises a grip or a connecting rod, or a first end of the grip is pivoted to the assembling body, or a second end of the grip penetrates out of a front groove or is connected to a fastener, or a second chute is formed between the two ends of the grip, or a first end of the connecting rod is pivoted to a first chute or the second chute, or the second end of the connecting rod is provided with a jacking portion, or a third chute is formed between the two ends of the connecting rod, or the third chute is pivoted to the assembling body, or the assembling body is provided with the front groove, a side groove or the first chute or a clamping portion;
or when the assembly is in a lock state, the jacking portion penetrates out of the side groove, or the fastener is connected to the clamping portion; or when the assembly is in an open state, the jacking portion retracts into the assembling body, or the fastener moves away from the assembling body.

2. The assembly according to claim 1, wherein the assembling body is provided with a first housing and a second housing, the assembling body is provided with a fixed shaft rod, a first sliding shaft rod and a second sliding shaft rod connected to the first housing and/or the second housing, the fixed shaft rod penetrates through the first end of the grip, the first sliding shaft rod penetrates through the first chute and the second chute, and the second sliding shaft rod penetrates through the third chute.

3. The assembly according to claim 2, wherein each of the first housing and the second housing is provided with two through holes and an elongated slot, the fixed shaft rod and the second sliding shaft rod penetrate through the two corresponding through holes of the first housing and the second housing respectively, and the two elongated slots jointly form the first chute.

4. The assembly according to claim 1, wherein the grip is provided with a first corner portion connected to a first base and a first outward-turning portion, a first obtuse angle is formed between an extension direction of the first base and an extension direction of the first outward-turning portion, the second chute is positioned in the first outward-turning portion, and the fastener is connected to the first base.

5. The assembly according to claim 4, wherein the connecting rod is provided with a second corner portion connected to a second base and a second outward-turning portion, a second obtuse angle is formed between an extension direction of the second base and an extension direction of the second outward-turning portion, the jacking portion is positioned on the second outward-turning portion and is located within the range of the second obtuse angle, and the third chute is positioned in the second base.

6. The assembly according to claim 5, wherein the connecting rod is provided with a third outward-turning portion connected to the second base, a third obtuse angle is formed between the extension direction of the second base and an extension direction of the third outward-turning portion, and the second obtuse angle and the third obtuse angle are alternate interior angles relative to each other.

7. The assembly according to claim 6, wherein the extension direction of the second outward-turning portion is parallel to the extension direction of the third outward-turning portion.

8. The assembly according to claim 6, wherein the first outward-turning portion of the grip is provided with a side slot, and the second chute is aligned in the side slot, the third outward-turning portion of the connecting rod is a thin sheet, the third outward-turning portion penetrates into the side slot, and the assembling body is provided with the first sliding shaft rod penetrating through the first chute, the second chute, the side slot and the third outward-turning portion.

9. The assembly according to claim 1, wherein one end of the fastener is provided with a fastening body, the other end is abutted by an elastic member, and the two ends of the fastener are pivoted to the second end of the grip.

10. The assembly according to claim 1, wherein the assembling body is arranged or assembled or integrally formed in a data center or a case or a cabinet or a computer or a sliding rail or a mainboard or a printed circuit board or a metallic body or a nonmetallic body or a plastic body or a housing or an object, or the jacking portion is configured to jack or hook or push the case or the cabinet or the computer or the sliding rail or the mainboard or the printed circuit board or the metallic body or the nonmetallic body or the plastic body or the housing or the object, or the jacking portion is configured to jack or hook or push the case or the cabinet or the computer or the sliding rail or the mainboard or the printed circuit board or the metallic body or the nonmetallic body or the plastic body or the housing or the object to move the object arranged or assembled or integrally formed by the assembling body.
